(19) United States
(12) Patent Application Publication
(10) Pub. No.: US 2026/0179523 A1
(43) Pub. Date: Jun. 25, 2026

(54) DISPLAY DEVICE AND DISPLAY DRIVING CIRCUIT

(71) Applicant: MAGNACHIP SEMICONDUCTOR, LTD., Cheongju-si (KR)

(72) Inventors: Myungwoo LEE, Seongnam-si (KR); Wooyoung LIM, Seoul (KR)

(73) Assignee: MAGNACHIP SEMICONDUCTOR, LTD., Cheongju-si (KR)

(21) Appl. No.: 19/242,880

(22) Filed: Jun. 18, 2025

(30) Foreign Application Priority Data
Dec. 24, 2024 (KR) 10-2024-0194915

(51) Int. Cl. G09G 3/20; G09G 3/3233

(52) U.S. Cl. CPC G09G 3/2092; G09G 3/3233; G09G 2300/0842; G09G 2310/0291; G09G 2320/0626; G09G 2330/021

(57) ABSTRACT

A display driving device for driving a display panel includes a timing controller configured to output a bias control signal and video data based on a display brightness value (DBV) received from an external source; and a source driver configured to output a data line voltage to a plurality of channels based on the bias control signal and the video data.

### CROSS REFERENCE TO RELATED APPLICATION

The present application claims the benefit under 35 U.S.C. § 119 (a) of Korean Patent Application No. 10-2024-0194915, filed on Dec. 24, 2024, in the Korea Intellectual Property Office, the entire disclosure of which is incorporated herein by reference for all purposes.

### BACKGROUND

### 1. Field

The present disclosure relates to a display device and a display driving device that can improve the power consumption of a source driver.

### 2. Description of Related Art

A display device may include a display panel and a display driving device configured to control the display panel. The display driving device may transmit data signals to the display panel.

The display driving device may be implemented as one or more integrated circuits (ICs), which are referred to as display driver IC (DDICs). DDICs are widely used in devices such as portable electronic devices (e.g., smartphones and tablet personal computers) and vehicle displays (digital instrument panels, navigation systems, etc.). DDIC is a source driving circuit for driving panels such as liquid crystal displays (LCDs) and organic light emitting diode (OLED) devices, and includes an output buffer circuit for data output. There is an increasing demand for performance improvements related to the high resolution, display quality, and low power consumption of DDICs.

The output buffer circuit of DDIC maintains both low and high voltages using a rail-to-rail amplifier. However, there is a problem with increasing power consumption if a rail-to-rail amplifier is always used regardless of the output voltage of the source driving circuit.

For example, a typical DDIC for OLED requires a PMOS input circuit and a PMOS tail circuit to output low voltage at high brightness. However, the PMOS input circuit and PMOS tail circuit always cause current to flow, which increases power consumption.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Accordingly, various examples of the present disclosure are directed to providing a method of reducing current consumption, in which a display brightness value (DBV), which does not need to use some of input stage circuits of an amplifier, is defined and in the corresponding DBV, a bias circuit of the input stage circuit is turned off to prevent a flow of a current. In addition, various examples of the present disclosure are directed to providing a display driving device and a display device to which the above method is applied.

Objects of the present document are not limited to the above-described objects, and other objects that are not described will be able to be clearly understood by those skilled in the art to which the present disclosure pertains from the following description.

In one general aspect, a display driving device for driving a display panel includes a timing controller configured to output a bias control signal and video data based on a display brightness value (DBV) received from an external source; and a source driver configured to output a data line voltage to a plurality of channels based on the bias control signal and the video data.

The source driver may include an input circuit configured to output the video signal distinguished based on a channel of the source driver by distinguishing the video data which is input based on a line; a conversion circuit configured to output an analog voltage corresponding to the video data distinguished based on the channel; and an output circuit configured to output the data line voltage to the display panel based on the analog voltage and the bias control signal.

The output circuit may include a plurality of amplifiers provided in each channel of the source driver and configured to amplify the analog voltage based on the bias control signal and output the data line voltage.

The timing controller may include a first bias control logic configured to generate a first bias control signal, and a second bias control logic configured to generate a second bias control signal.

The first bias control logic may be configured to provide the first bias control signal to the source driver according to a first option signal of a high level and a first option complementary signal of a low level.

The second bias control logic may be configured to provide the second bias control signal to the source driver according to a second option signal of a high level and a second option complementary signal of a low level.

Each amplifier may include an output stage including a first output transistor and a second output transistor; and an input stage including a first bias circuit configured to provide a first bias current, a first input stage configured to determine a first differential current and a second differential current, which correspond to a difference between an input voltage and an output voltage, based on the first bias current, a second bias circuit configured to provide a second bias current, and a second input stage configured to determine a third differential current and a fourth differential current, which correspond to a difference between the input voltage and the output voltage, based on the second bias current. The first bias circuit may be configured to provide or not provide the first bias current based on the bias control signal, and the second bias circuit may be configured to provide or not provide the second bias current based on the bias control signal.

Each amplifier may further include a load stage configured to control gate voltages of the first output transistor and the second output transistor based on the first differential current and the second differential current which are applied from the input stage and the third differential current and the fourth differential current which are transmitted to the input stage.

The timing controller may be configured to: classify settable display brightness values (DBVs) into a plurality of bands, set a minimum and maximum data line voltage for each band, determine a first band to which the received DBV belongs, and compare the minimum and maximum data line voltage of the first band with a reference voltage and generate the bias control signal.

When the minimum data line voltage of the first band is lower than a first reference voltage and the maximum data line voltage of the first band is higher than a second reference voltage, the timing controller may be configured to generate the bias control signal which allows the first bias circuit and the second bias circuit to provide the first bias current and the second bias current.

When the minimum data line voltage of the first band is higher than a first reference voltage, the timing controller may be configured to generate the bias control signal which allows the second bias circuit to provide the second bias current.

When the maximum data line voltage of the first band is lower than a second reference voltage, the timing controller may be configured to generate the bias control signal which allows the first bias circuit to provide the first bias current.

The timing controller may include a lookup table (LUT) for generating the bias control signal, the LUT including a minimum and maximum data line voltage corresponding to a band to which each DBV belongs and a bias control signal corresponding to each band. The timing controller may be configured to generate the bias control signal according to the received DBV based on the LUT.

In another general aspect, a method of operating a display driving device for driving a display panel, the method includes: receiving a video signal to be displayed on the display panel, generating video data according to a frame structure based on the video signal, generating a bias control signal based on a display brightness value (DBV) received from an external source, determining whether a first bias control circuit and a second bias control circuit, which are provided in an input stage of an amplifier included in a source driver, provide a first bias current and a second bias current based on the bias control signal, and generating a data line voltage based on at least one of the first bias current and the second bias current and the video data and outputting the generated data line voltage to the display panel.

The generating of the data line voltage based on the video data and the outputting of the generated data line voltage to the display panel may include: distinguishing the video data, which is input based on a line, based on a channel of the source driver and outputting the distinguished video data; outputting an analog voltage corresponding to the video data distinguished based on the channel; and amplifying the analog voltage based on at least one of the first bias current and the second bias current based on the channel and outputting the amplified analog voltage to the display panel.

The generating of the bias control signal based on the DBV received from the external source may include: classifying settable DBVs into a plurality of bands; setting a minimum and maximum data line voltage for each band; determining a first band to which the received DBV belongs; and comparing the minimum and maximum data line voltage of the first band with a reference voltage and generating the bias control signal.

The comparing of the minimum and maximum data line voltage of the first band with the reference voltage and the generating of the bias control signal may include generating the bias control signal which allows the first bias circuit and the second bias circuit to provide the first bias current and the second bias current when the minimum data line voltage of the first band is lower than a first reference voltage and the maximum data line voltage is higher than a second reference voltage.

The comparing of the minimum and maximum data line voltage of the first band with the reference voltage and the generating of the bias control signal may include generating the bias control signal which allows the second bias circuit to provide the second bias current when the minimum data line voltage of the first band is higher than a first reference voltage.

The comparing of the minimum and maximum data line voltage of the first band with the reference voltage and the generating of the bias control signal may include generating the bias control signal which allows the first bias circuit to provide the first bias current when the maximum data line voltage of the first band is lower than a second reference voltage.

The comparing of the minimum and maximum data line voltage of the first band with the reference voltage and the generating of the bias control signal may include setting a lookup table (LUT) including a minimum and maximum data line voltage corresponding to a band to which each DBV belongs and a bias control signal corresponding to each band, and generating the bias control signal according to the DBV based on the LUT.

Other features and aspects will be apparent from the following detailed description, the drawings, and the claims.

### BRIEF DESCRIPTION OF THE DRAWINGS

FIG. 1 illustrates a display device according to one example of the present disclosure.

FIG. 2 illustrates a sub-pixel structure according to one example.

FIG. 3 illustrates a source driver according to one example.

FIG. 4 illustrates a block diagram illustrating an amplifier according to one example of the present disclosure.

FIG. 5 illustrates a circuit diagram illustrating an input stage and a bias circuit according to one example of the present disclosure.

FIG. 6 illustrates a circuit of a load stage and an output stage according to one example of the present disclosure.

FIGS. 7a and 7b illustrate examples of data line voltages output to each channel by a source driver according to display brightness values (DBVs) and gamma values.

FIGS. 8a and 8b illustrate a bias control logic illustrated in FIG. 1.

FIG. 9 illustrates a flowchart illustrating a method of determining whether to use only one of a first input stage or a second input stage according to the DBV.

FIGS. 10a to 10c illustrate examples of the operation of an input stage controlled according to the operation of FIG. 9.

FIG. 11 illustrates a flowchart illustrating a method of operating a display driving device according to one example of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

Advantages and features of the present disclosure and methods for achieving them will become clear with reference to examples described below in detail in conjunction with the accompanying drawings. However, the present disclosure is not limited to the examples disclosed below but can be implemented in various different forms, these examples are merely provided to make the disclosure of the present disclosure complete and fully inform those skilled in the art to which the present disclosure pertains of the scope of the present disclosure, and the present disclosure is only defined by the scope of the appended claims. The same reference number denotes the same components throughout the specification.

The use of the term “may” herein with respect to an example or embodiment, e.g., as to what an example or embodiment may include or implement, means that at least one example or embodiment exists where such a feature is included or implemented, while all examples are not limited thereto.

When a first component is “connected to” or “coupled to” a second component, it includes both a case in which the first component is directly connected or coupled to the second component or a case in which other components are interposed therebetween. On the other hand, when the first component is “directly connected to” or “directly coupled to” the second component, it means that other components are not interposed therebetween. The term “and/or” includes each of stated items and any combination of one or more.

Terms used in the specification are for describing the examples and are not intended to limit the present disclosure. In the present specification, the singular form also includes the plural form unless specifically stated in the phrase. As used herein, “comprises” and/or “comprising” means that the stated component, step, operation, and/or element do not preclude the presence of addition of one or more other components, steps, operations, and/or elements.

Although first, second, and the like are used to describe various components, it goes without saying that these components are not limited by these terms. These terms are only used to distinguish one component from another component.

Therefore, it goes without saying that a first component to be described below may be a second component within the technical spirit of the present disclosure. Unless otherwise defined, all terms (including technical and scientific terms) used in the specification may be used as meaning commonly understood by those skilled in the art to which the present disclosure pertains. In addition, terms defined in commonly used dictionaries are not construed ideally or excessively unless clearly and specially defined.

The term “unit” or “module” used in the present example is software or a hardware component such as a field programmable gate array (FPGA) or an application specific integrated circuit (ASIC), and the “unit” or “module” performs certain functions. However, the “unit” or “module” is not limited to software or hardware. The “unit” or “module” may be configured to be disposed in an addressable storage medium and configured to play one or more processors. Therefore, as an example, the “unit” or “module” is components such as software components, object-oriented software components, class components, and task components, processes, functions, properties, procedures, subroutines, segments of program code, drivers, firmware, microcode, circuitry, data, databases, data structures, tables, arrays, and variables. Functions provided in components and “units” or “modules” may be combined into the smaller number of components and “unit” or “modules” or separated into additional components and “units” or “modules.”

Operations of a method or algorithm described in connection with some examples of the present disclosure may be implemented directly in hardware and software modules executed by a processor or a combination of the two. The software modules may reside in a RAM, a flash memory, a ROM, an EPROM, an EEPROM, a register, a hard disk, a removable disk, a CD-ROM, or any other form of recording medium known in the art. An exemplary recording medium is coupled to a processor, and the processor may read information from the recording medium and write the information to the storage medium. As another method, the recording medium may be integrated with the processor. The processor and the recording medium may reside in an ASIC. The ASIC may reside in a user terminal.

Hereinafter, examples of the present disclosure will be described in detail with reference to the accompanying drawings so that those skilled in the art to which the present disclosure pertains may easily carry out the present disclosure. However, the present disclosure may be implemented in various different forms and is not limited to examples described herein.

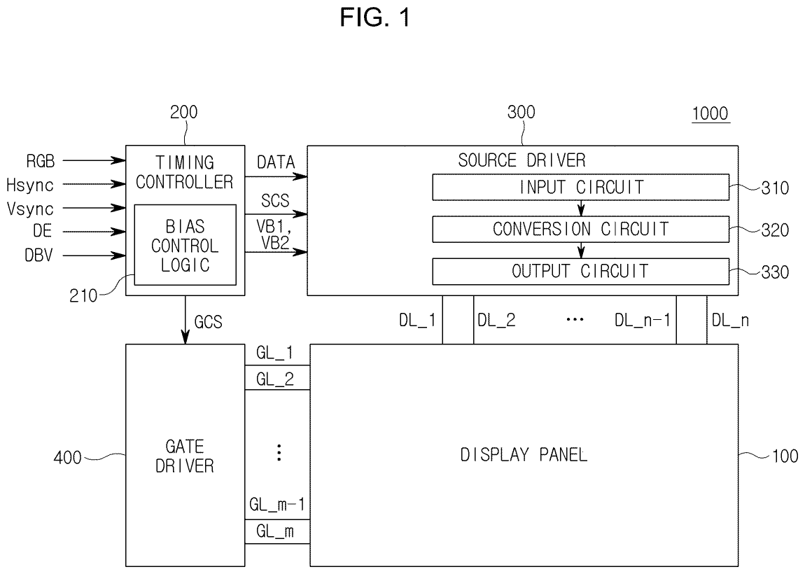

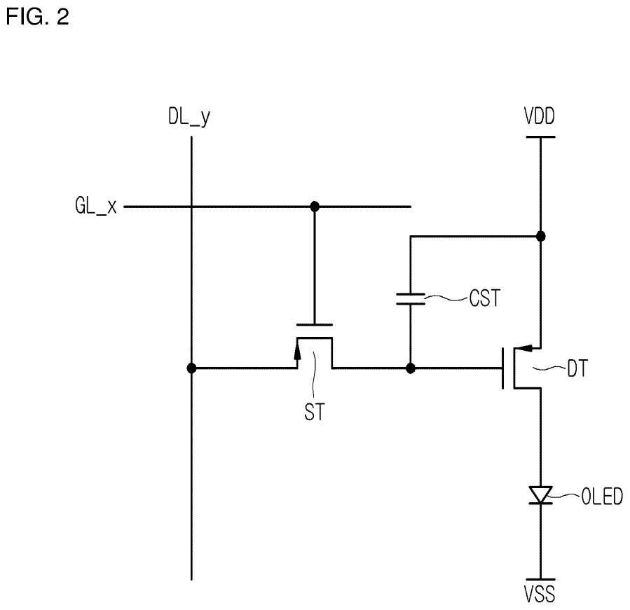

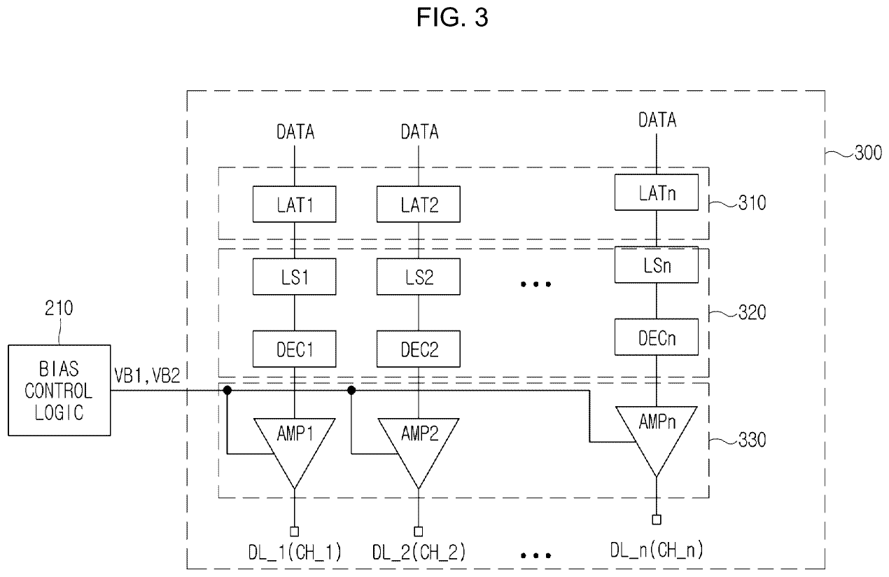

FIG. 1 illustrates a display device according to one example of the present disclosure, FIG. 2 illustrates a sub-pixel structure according to one example, and FIG. 3 illustrates a source driver according to one example.

Referring to FIG. 1, a display device 1000 may include a display panel 100, a timing controller 200, a source driver 300, and a gate driver 400.

According to one example, the display device 1000 may be a device capable of displaying an image or video. For example, the display device 1000 may be a device provided in a smartphone, a tablet personal computer (PC), a mobile phone, a video phone, an e-book reader, a computer, a camera, a wearable device, and the like and may be a device provided in various devices which need to display an image or video.

According to one example, the display panel 100 may include a plurality of sub-pixels PX (not illustrated) arranged in rows and columns. The plurality of sub-pixels PX may be displayed in a grid structure formed of m rows and n columns (m and n are natural numbers).

For example, the display panel 100 may be implemented as one of a liquid crystal display (LCD), a light emitting diode (LED) display, an organic LED (OLED) display, an active-matrix OLED (AMOLED) display, an electrochromic display (ECD), a digital mirror device (DMD), an actuated mirror device (AMD), a grating light valve (GLV), a plasma display panel (PDP), an electro luminescent display (ELD), and a vacuum fluorescent display (VFD), but is not limited thereto.

According to one example, the display panel 100 may include m gate lines GL_1 to GL_m arranged in m rows, and n data lines DL_1 to DL_n arranged in n columns. The sub-pixels PX may be disposed at intersections of the gate lines GL1 to GL_m and the data lines DL_1 to DL_n.

According to one example, the sub-pixels PX of the display panel 100 may be driven on the basis of a gate line. For example, during a first time, the sub-pixels arranged in one gate line may be driven, and during a second time following the first time, the sub-pixels arranged in another gate line may be driven. In this case, a unit time during which the sub-pixels PX are driven may be referred to as one horizontal (1H) scan time.

According to one example, as illustrated in FIG. 2, the sub-pixels PX may include a light emitting element configured to output light and a light emitting element driving circuit configured to drive the light emitting element. The light emitting element driving circuit may be connected to one gate line GL_x and one data line DL_y, and the light emitting element may be connected between the light emitting element driving circuit and a power voltage (e.g., a ground voltage VSS).

For example, the light emitting element may be an LED, an OLED, a quantum dot LED (QLED), or a micro LED, but is not limited thereto.

According to one example, each of the sub-pixels PX may be one of a red element R which outputs red light, a green element G which outputs green light, a blue element B which outputs blue light, and a white element W which outputs white light, and the red element, the green element, the blue element, and the white element may be arranged in various ways on the display panel 100. The sub-pixels PX of the display panel 100 may be repeatedly arranged in the order of R, G, B, G or B, G, R, G or R, G, B, W. For example, the sub-pixels PX of the display panel 100 may be arranged according to an RGB stripe structure, an RGB pentile structure, an RGBW array structure, but is not limited thereto.

According to one example, the light emitting element driving circuit may include switching elements ST, such as thin film transistors (TFTs), connected to the gate lines GL1 to GL_m. When a gate-on signal is applied from the gate line GL_x (x is a natural number from 1 to m) to turn on the switching element ST, the light emitting element driving circuit may supply the light emitting element with a data signal (or a pixel signal) received from a data line DL_y (y is a natural number from 1 to n) connected to the light emitting element driving circuit. The light emitting element may output light corresponding to a video signal.

According to one example, a timing controller 200 may receive video signals RGB from the external source and perform video processing on the video signals RGB or convert the video signals RGB according to a structure of the display panel 100 to generate video data DATA. The timing controller 200 may generate the video data DATA capable of being distinguished on the basis of a gate line.

According to one example, the timing controller 200 may distinguish the video data DATA on the basis of a line on the basis of a channel of the source driver 300 to generate the video data DATA. The timing controller 200 may generate the video data DATA on the basis of a line, which may be distinguished on the basis of a channel of the source driver 300. The timing controller 200 may transmit the video data DATA to the source driver 300. The timing controller 200 may transmit the video data DATA on the basis of a line to the source driver 300 for each horizontal scan time.

According to one example, the timing controller 200 may receive a plurality of control signals from an external host device. The control signals received from the host device may include a horizontal synchronization signal Hsync, a vertical synchronization signal Vsync, and a data enable signal DE.

According to one example, the timing controller 200 may generate a source control signal SCS and a gate control signal GCS for controlling the source driver 300 and the gate driver 400 based on the received control signals. The timing controller 200 may generate the source control signal SCS and the gate control signal GCS based on the horizontal synchronization signal Hsync.

According to one example, the timing controller 200 may control the operation timing of the source driver 300 and the gate driver 400 based on the source control signal SCS and the gate control signal GCS.

According to one example, the timing controller 200 may transmit the source control signal SCS to the source driver 300, and the source driver 300 may output data signals to the plurality of data lines DL1 to DL_n based on the received source control signal SCS. The timing controller 200 may transmit the gate control signal GCS to the gate driver 400, and the gate driver 400 may output gate signals to the plurality of gate lines GL1 to GL_m based on the received gate control signal GCS.

According to one example, the timing controller 200 may include a bias control logic 210 for outputting bias control signals VB1 and VB2. The bias control logic 210 may classify settable display brightness values (DBVs) into a plurality of bands BAND and set a minimum data line voltage or a maximum data line voltage to be used in the corresponding band. As will be described below, the lower the data line voltage, the brighter the pixel may be displayed. In addition, the bias control logic 210 may set the bias control signal based on the DBV received from the host. According to one example, the bias control logic 210 may have a lookup table (LUT) shown in Table 1 below. The LUT shown in Table 1 may include the minimum data line voltage and information PTAIL_OFF_EN representing whether to turn off or on a first input stage 510 or second input stage 520 circuit according to each band of the DBV.

TABLE 1

| DBV | BAND | Minimum data line voltage | PTAIL_OFF_EN |
|---|---|---|---|
| 939 to 1023 | 0 | 1.4 V | 0 |
| 853 to 938 | 1 | 1.6 V | 0 |
| 768 to 852 | 2 | 1.8 V | 0 |
| 683 to 767 | 3 | 2.0 V | 0 |
| 597 to 682 | 4 | 2.2 V | 0 |
| 512 to 596 | 5 | 2.4 V | 0 |
| 427 to 511 | 6 | 2.6 V | 1 |
| 341 to 426 | 7 | 2.8 V | 1 |
| 256 to 340 | 8 | 3.0 V | 1 |
| 171 to 255 | 9 | 3.2 V | 1 |
| 85 to 170 | 10 | 3.4 V | 1 |
| 0 to 84 | 11 | 3.6 V | 1 |

The bias control logic 210 may determine whether to turn off or on the input stage circuit formed of a PMOS based on the received DBV with reference to the LUT of Table 1. In addition, based on the above determination, the bias control logic 210 may transmit the bias control signals VB1 and VB2 to the source driver 300. The source driver 300 may turn on/off a switch which provides a bias current to an output circuit based on the received bias control signals VB1 and VB2.

A specific configuration and operation of the bias control logic 210 will be described in more detail below.

According to one example, the source driver 300 may output data signals to the display panel 100 based on the video data DATA. The source driver 300 may generate data signals corresponding to videos displayed on the display panel 100 based on the video data DATA and transmit the generated data signals to the display panel 100. The data signals may be transmitted to each of the sub-pixels PX. For example, the source driver 300 may transmit data signals to be displayed during the 1H time to sub-pixels PX driven during the 1H time through data lines DL_1 to DL_n.

According to one example, the source driver 300 may receive the video data DATA and generate data signals using gamma values corresponding to the video data DATA. Each of the data signals corresponds to the video data DATA and is a signal for driving each of the sub-pixels PX. For example, the source driver 300 may output n data signals to the display panel 100.

According to one example, the source driver 300 may generate the data signals based on the source control signal SCS. For example, the source control signal SCS may include a source start signal, a source shift clock signal, a source output enable signal, and the like.

According to one example, referring to FIGS. 1 and 3, the source driver 300 may include an input circuit 310, a conversion circuit 320, and an output circuit 330.

According to one example, the input circuit 310 may separately output the video data DATA, which is received from the timing controller 200 on the basis of a line, by channel of the source driver 300.

The input circuit 310 may receive the video data DATA transmitted from the timing controller 200, latch the video data DATA, and output the latched video data DATA to the conversion circuit 320.

According to one example, latches LAT1 to LATn corresponding to each channel provided in the input circuit 310 may receive the video data DATA represented as continuous bits, then latch some of the video data DATA corresponding to the corresponding channel, and output the latched video data DATA to the conversion circuit 320. For example, the input circuit 310 may receive 8n bits of video data DATA, latch 8 bits corresponding to each channel among the 8n bits of video data DATA, and output the 8 bits to the conversion circuit 320.

According to one example, the conversion circuit 320 may generate analog voltages using the video data DATA output from the input circuit 310. The conversion circuit 320 may generate gamma voltages, which are analog voltages corresponding to data values of the video data DATA.

The conversion circuit 320 may determine the analog voltages corresponding to the data values of the video data DATA using pre-stored reference gamma voltages. The conversion circuit 320 may interpolate the pre-stored reference gamma voltages to determine the analog voltages corresponding to the data values of the video data DATA. The conversion circuit 320 may transmit the generated analog voltages to the output circuit 330.

For example, the conversion circuit 320 may include level shifters LS1 to LSn for changing levels of the video data DATA transmitted from the input circuit 310 and decoder DEC1 to DECn for generating analog voltages using video data (which have converted levels) transmitted from the level shifters LS1 to LSn. According to one example, the decoders DEC1 to DECn may generate the analog voltages using a method of selecting one of the plurality of gamma voltages based on the video data of the corresponding channel, which has the converted level.

According to one example, the output circuit 330 may receive the analog voltages, amplify the analog voltages using amplifiers AMP1 to AMPn, and then output the amplified analog voltages to the display panel 100. Here, the amplifier may be provided for each channel CH_1, CH_2, . . . , CH_n. The output circuit 330 may or may not supply bias currents based on the bias control signals VB1 and VB2 supplied from the bias control logic 210.

According to one example, the gate driver 400 may sequentially provide gate signals to the plurality of gate lines GL_1 to GL_m in response to the gate control signal GCS. For example, the gate control signal GCS may include a gate start pulse, which instructs the output start of a gate signal, and a gate shift clock, which controls the output timing of a gate on signal.

According to one example, when the gate start pulse is applied, the gate driver 400 may generate a gate pulse in response to the gate shift clock and sequentially provide gate signals to the gate lines GL_1 to GL_m using the gate pulse. Each of the gate signals is a signal for turning on the sub-pixels PX connected to each of the gate lines GL_1 to GL_m and may be applied to a gate terminal of a transistor included in each of the sub-pixels PX.

According to one example, the gate driver 400 may transmit a gate signal of a high logic level to the gate line to which the sub-pixels PX to be driven are connected and transmit a gate signal of a low logic level to the gate line to which the sub-pixels PX which are not driven are connected. The gate signal of the high logic level may be referred to as a gate on signal, and the gate signal of the low logic level may be referred to as a gate off signal.

The timing controller 200, the source driver 300, and the gate driver 400 may be referred to as display driving devices for controlling the display panel 100. In addition, the timing controller 200, the source driver 300, and the gate driver 400 may be implemented as one integrated circuit or as separate integrated circuits. In addition, according to examples, the gate driver 400 may be implemented by being mounted on the display panel 100.

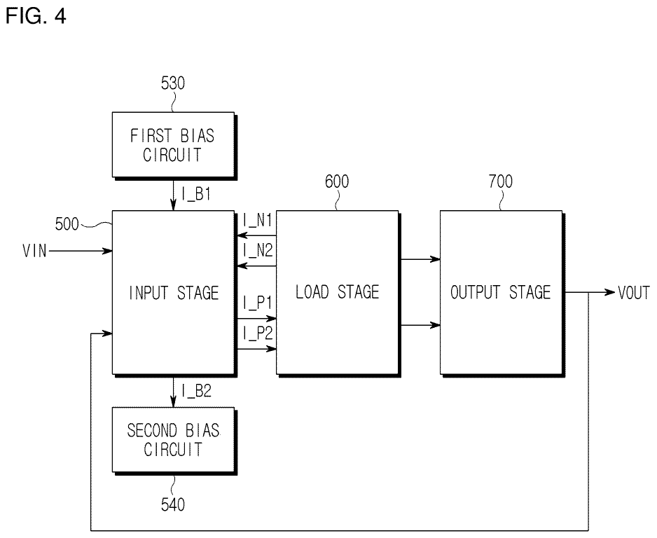

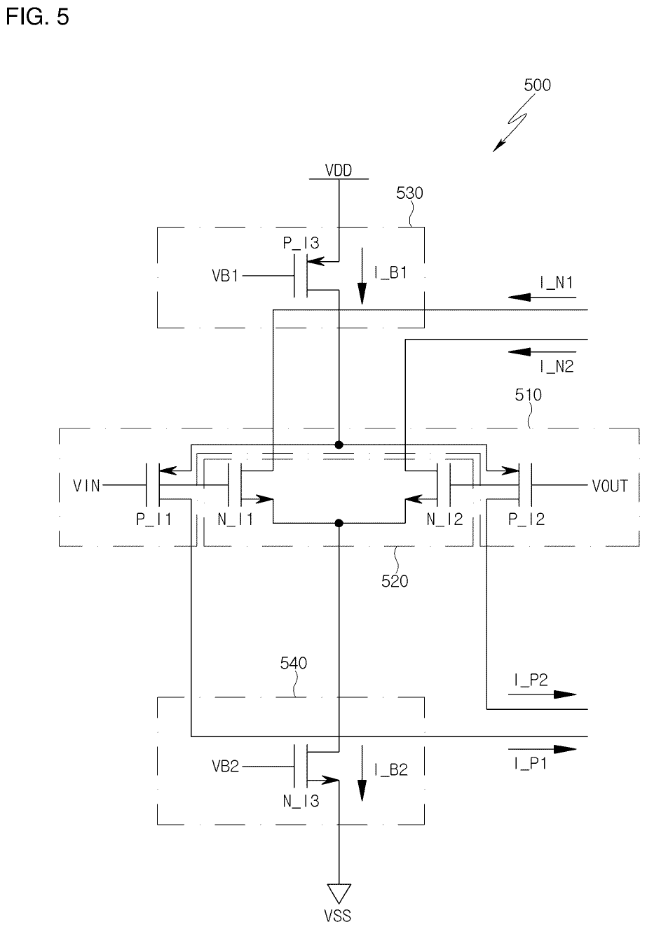

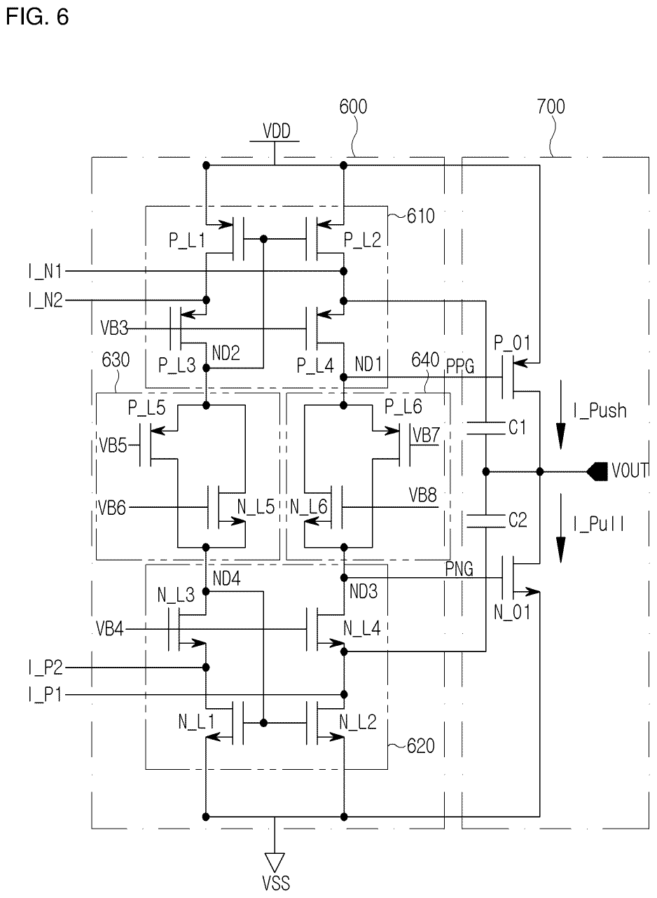

FIG. 4 illustrates a block diagram illustrating an amplifier according to one example of the present disclosure. In the following examples, specific structures of components illustrated in FIG. 4 will be described with reference to FIGS. 5 and 6. FIG. 5 illustrates a circuit diagram illustrating an input stage and a bias circuit according to one example of the present disclosure, and FIG. 6 illustrates a circuit of a load stage and an output stage according to one example of the present disclosure.

Referring to FIG. 4, an amplifier AMP according to one example of the present disclosure may include an input stage 500, a load stage 600, and an output stage 700. The amplifier AMP may amplify an input voltage VIN and output an output voltage VOUT. When the input voltage VIN increases or decreases, the amplifier AMP may output the output voltage VOUT which increases or decreases by following the input voltage VIN. The amplifier AMP may feedback the output voltage VOUT, compare the feedback output voltage VOUT with the input voltage VIN, and adjust the output voltage VOUT based on a difference in the output voltages VOUT. The amplifier AMP may improve a slew rate of a rising transition of the input voltage VIN so that the output voltage VOUT may quickly follow the input voltage VIN. In addition, the amplifier AMP may improve a slew rate of a falling transition of the input voltage VIN so that the output voltage VOUT may quickly follow the input voltage VIN.

The input stage 500 may transmit first and second differential currents I_P1 and I_P2 to the load stage 600 based on a difference between the input voltage VIN and the output voltage VOUT output from the output stage 700. In addition, the input stage 500 may receive third and fourth differential currents I_N1 and I_N2 from the load stage 600 based on a difference between the input voltage VIN and the output voltage VOUT output from the output stage 700. Here, the sum of the first and second differential currents I_P1 and I_P2 and the sum of the third and fourth differential currents I_N1 and I_N2 may be the same. For example, when the input voltage VIN is higher than the output voltage VOUT, the second differential current I_P2 and the third differential current I_N1 increase and the first differential current I_P1 and the fourth differential current I_N2 decrease, and thus the sum of the first and second differential currents I_P1 and I_P2 and the sum of the third and fourth differential currents I_N1 and I_N2 may be the same.

The input stage 500 may have a rail-to-rail structure having a dual structure. The input stage 500 may be connected between a power supply voltage VDD and a ground voltage VSS.

The input stage 500 may be connected to a first bias circuit 530. The input stage 500 may receive a first bias current I_B1 for operating an internal PMOS transistor from the first bias circuit 530. Here, the first bias current I_B1 may serve as a constant current source which makes the sum of the first and second differential currents I_P1 and I_P2 flowing in the internal PMOS transistor of the input stage 500 constant.

The input stage 500 may be connected to a second bias circuit 540. The input stage 500 may transmit a second bias current I_B2 to the second bias circuit 540 so that an internal NMOS transistor operates. Here, the second bias current may serve as a constant current source which makes the sum of the third and fourth differential currents I_N1 and I_N2 flowing in the internal NMOS transistor of the input stage 500 constant.

The first bias circuit 530 may be disposed between the power supply voltage VDD and the input stage 500. The first bias circuit 530 may be connected to the power supply voltage VDD and the input stage 500. The first bias circuit 530 may transmit the first bias current I_B1 to the input stage 500 as a constant current source.

The second bias circuit 540 may be disposed between the ground voltage VSS and the input stage 500. The second bias circuit 540 may be connected to the ground voltage VSS and the input stage 500. The second bias circuit 540 may receive the second bias current I_B2 from the input stage 500 as a constant current source.

The load stage 600 may receive the first and second differential currents I_P1 and I_P2 from the input stage 500. The load stage 600 may transmit the third and fourth differential currents I_N1 and I_N2 to the input stage 500. The load stage 600 may receive the first and second differential currents I_P1 and I_P2 from the input stage 500 based on the difference between the input voltage VIN and the output voltage VOUT. The load stage 600 may transmit the third and fourth differential currents I_N1 and I_N2 to the input stage 500 based on the difference between the input voltage VIN and the output voltage VOUT.

The load stage 600 may increase or decrease gate voltages of output transistors of the output stage 700 based on the first to fourth differential currents I_P1, I_P2, I_N1, and I_N2. The load stage 600 may perform a current mirroring operation based on the first to fourth differential currents I_P1, I_P2, I_N1, and I_N2 and allow a current to flow into or out of nodes connected to gate terminals of the output transistors of the output stage 700. When the current flows into the nodes connected to the gate terminals of the output transistors of the output stage 700, the gate voltages of the output transistors may increase. On the other hand, when the current flows out of the nodes connected to the gate terminals of the output transistors, the gate voltage of the output transistors may decrease. When the gate voltage of the output transistors increases, the output voltage VOUT may decrease, and on the other hand, when the gate voltage of the output transistors decreases, the output voltage VOUT may increase.

According to one example, although not illustrated in FIG. 4, a circuit for compensating for a slew rate of the output voltage VOUT may be additionally connected to the load stage 600.

Hereinafter, a specific structure of the amplifier AMP according to one example of the present disclosure will be described with reference to FIGS. 5 and 6.

Referring to FIGS. 5 and 6, the input stage 500 may include a first input stage 510 formed of PMOS transistors P_I1 and P_I2, a second input stage 520 formed of NMOS transistors N_I1 and N_I2, a first bias circuit 530 for providing the first bias current I_B1 to the first input stage 510, and a second bias circuit 540 for providing the second bias current I_B2 to the second input stage 520.

The load stage 600 may include a first differential mirror circuit 610, a second differential mirror circuit 620, a third bias circuit 630, and a fourth bias circuit 640. According to one example, the first differential mirror circuit 610 and the second differential mirror circuit 620 may have a cascode structure and perform a current mirroring operation.

The output stage 700 may include first and second output transistors P_O1 and N_O1 and first and second compensation capacitors C1 and C2.

The first input stage 510 may be formed of a first input stage PMOS transistor P_I1 and a second input stage PMOS transistor P_I2.

The first input stage PMOS transistor P_I1 may have a gate which receives the input voltage VIN, a source connected in common to the first bias circuit 530 along with the second input stage PMOS transistor P_I2, and a drain connected to the second differential mirror circuit 620 of the load stage 600. The first input stage PMOS transistor P_I1 may transmit the first differential current I_P1 output based on the input voltage VIN to the drain of the second load stage NMOS transistor N_L2 of the second differential mirror circuit 620 of the load stage 600.

The second input stage PMOS transistor P_I2 may have a gate which receives the output voltage VOUT, a source connected in common to the first bias circuit 530 along with the first input stage PMOS transistor P_I1, and a drain connected to the second differential mirror circuit 620 of the load stage 600. The second input stage PMOS transistor P_I2 may transmit the second differential current I_P2 output based on the output voltage VOUT to the drain of the first load stage NMOS transistor N_L1 of the second differential mirror circuit 620 of the load stage 600.

When the input voltage VIN and the output voltage VOUT are the same, the first differential current I_P1 and the second differential current I_P2 may be transmitted to the load stage 600 with the same current value, and when the input voltage VIN and the output voltage VOUT are different, the current values of the first differential current I_P1 and the second differential current I_P2 may be transmitted to the load stage 600 with a difference proportion to the difference.

The second input stage 520 may be formed of a first input stage NMOS transistor N_I1 and a second input stage NMOS transistor N_I2.

The first input stage NMOS transistor N_I1 may have a gate which receives the input voltage VIN, a source connected in common to the second bias circuit 540 along with the second input stage NMOS transistor N_I2, and a drain connected to the first differential mirror circuit 610 of the load stage 600. The first input stage NMOS transistor N_I1 may receive the third differential current I_N1 from the drain of the second load stage PMOS transistor P_L2 of the first differential mirror circuit 610 of the load stage 600 based on the input voltage VIN.

The second input stage NMOS transistor N_I2 may have a gate which receives the output voltage VOUT, a source connected in common to the second bias circuit 540 along with the first input stage NMOS transistor N_I1, and a drain connected to the first differential mirror circuit 610 of the load stage 600. The second input stage NMOS transistor N_I2 may receive the third differential current I_N2 from the drain of the first load stage PMOS transistor P_L1 of the first differential mirror circuit 610 of the load stage 600 based on the output voltage VOUT.

The first bias circuit 530 may be disposed between the power supply voltage VDD and the input stage 500. The first bias circuit 530 may be connected to the power supply voltage VDD and the input stage 500. The first bias circuit 530 may transmit the first bias current I_B1 to the input terminal 500 as a constant current source. The first bias circuit 530 may be formed of one PMOS transistor P_I3 or two PMOS transistors connected in series in a cascode structure.

The second bias circuit 540 may be disposed between the ground voltage VSS and the input stage 500. The second bias circuit 540 may be connected to the ground voltage VSS and the input stage 500. The second bias circuit 540 may receive the second bias current I_B2 from the input stage 500 as a constant current source. The second bias circuit 540 may be formed of one NMOS transistor N_I3 or two NMOS transistors connected in series in a cascode structure.

Referring to FIG. 6, the first differential mirror circuit 610 of the load stage 600 may serve as a constant current source, supply a current to the input stage 500, the third bias circuit 630, and the fourth bias circuit 640, and apply a voltage to gate terminals of the first output transistor P_O1 and the second output transistor N_O1 of the output stage 700.

The first differential mirror circuit 610 may include the first and second load stage PMOS transistors P_L1 and P_L2 which perform a current mirroring operation, and third and fourth load stage PMOS transistors P_L3 and P_L4 connected in series to the first and second load stage PMOS transistors P_L1 and P_L2 to form a cascode structure to have a high voltage gain.

Specifically, the first load stage PMOS transistor P_L1 of the first differential mirror circuit 610 may have a gate connected in common to the third bias circuit 630 along with the second load stage PMOS transistor P_L2, a drain connected to the third load stage PMOS transistor P_L3, and a source connected to the power supply voltage VDD.

The second load stage PMOS transistor P_L2 of the first differential mirror circuit 610 may have a gate connected in common to the third bias circuit 630 along with the first load stage PMOS transistor P_L1, a drain connected to the fourth load stage PMOS transistor P_L4, and a source connected to the power supply voltage VDD.

The third load stage PMOS transistor P_L3 of the first differential mirror circuit 610 may be connected between the third bias circuit 630 and the first load stage PMOS transistor P_L1. The third load stage PMOS transistor P_L3 may have a gate which receives a third bias voltage VB3, a drain at which a second node ND2 at which the third bias circuit 630 and the gates of the first load stage PMOS transistor P_L1 and the second load stage PMOS transistor P_L2 meet is positioned, and a source connected to the first load stage PMOS transistor P_L1.

The fourth load stage PMOS transistor P_L4 of the first differential mirror circuit 610 may be connected between the fourth bias circuit 640 and the second load stage PMOS transistor P_L2. The fourth load stage PMOS transistor P_L4 may have a gate which receives the third bias voltage VB3, a drain at which a first node ND1 at which the fourth bias circuit 640 and a gate terminal of the first output transistor P_O1 of the output stage 700 are connected is positioned, and a source connected to the second load stage PMOS transistor P_L2.

According to one example, the second differential mirror circuit 620 may have a cascode structure and perform a current mirroring operation.

The second differential mirror circuit 620 may serve as a constant current source, receive currents from the input stage 500, the third bias circuit 630, and the fourth bias circuit 640, and apply a voltage to the gate terminals of the first output transistor P_O1 and the second output transistor N_O1 of the output stage.

The second differential mirror circuit 620 may include the first and second load stage NMOS transistors N_L1 and N_L2 which perform a current mirroring operation, and third and fourth load stage NMOS transistors N_L3 and N_L4 connected in series to the first and second load stage NMOS transistors N_L1 and N_L2 to form a cascode structure to have a high voltage gain.

Specifically, the first load stage NMOS transistor N_L1 of the second differential mirror circuit 620 may have a gate connected in common to the third bias circuit 630 along with the second load stage NMOS transistor N_L2, a drain connected to the third load stage NMOS transistor N_L3, and a source connected to the ground voltage VSS.

The second load stage NMOS transistor N_L2 of the second differential mirror circuit 620 may have a gate connected in common to the third bias circuit 630 along with the first load stage NMOS transistor N_L1, a drain connected to the fourth load stage NMOS transistor N_L4, and a source connected to the ground voltage VSS.

The third load stage NMOS transistor N_L3 of the second differential mirror circuit 620 may be connected between the first load stage NMOS transistor N_L1 and the third bias circuit 630. The third load stage NMOS transistor N_L3 may have a gate which receives a fourth bias voltage VB4, a drain at which a fourth node ND4 at which the third bias circuit 630 and the gate of the first load stage NMOS transistor N_L1 are connected is positioned, and a source connected to the first load stage NMOS transistor N_L1.

The fourth load stage NMOS transistor N_L4 of the second differential mirror circuit 620 may be connected between the second load stage NMOS transistor N_L2 and the fourth bias circuit 640. The fourth load stage NMOS transistor N_L4 may have a gate which receives the fourth bias voltage VB4, a drain at which a third node ND3 at which the fourth bias circuit 640 and the gate terminal of the second output transistor N_O1 are connected is positioned, and a source connected to the second load stage NMOS transistor N_L2.

The third bias circuit 630 may include a fifth load stage PMOS transistor P_L5, which receives a fifth bias voltage VB5, and a fifth load stage NMOS transistor N_L5, which receives a sixth bias voltage VB6. The third bias circuit 630 may be positioned between the first differential mirror circuit 610 and the second differential mirror circuit 620. The third bias circuit 630 may control the operation and amplification operation of the first differential mirror circuit 610 and the second differential mirror circuit 620 in a static state. In addition, the third bias circuit 630 may be used as a floating current source and may adjust voltages of the second node ND2 and the fourth node ND4 with high impedance.

The fourth bias circuit 640 may include a sixth load stage PMOS transistor P_L6, which receives a seventh bias voltage VB7, and a sixth load stage NMOS transistor N_L6, which receives an eighth bias voltage VB8. The fourth bias circuit 640 may connect the first differential mirror circuit 610 to the second differential mirror circuit 620. The fourth bias circuit 640 may control the operation and amplification operation of the first differential mirror circuit 610 and the second differential mirror circuit 620 in a static state. In addition, the fourth bias circuit 640 may be used as a floating current source and may adjust voltages of the first node ND1 and the third node ND3 with high impedance.

The first output transistor P_O1 of the output stage 700 may have a gate connected to the first node ND1 of the first differential mirror circuit 610 of the load stage 600, a source connected to the power supply voltage VDD, and a drain connected to the output voltage VOUT. The current flowing in the first output transistor P_O1 may vary based on a voltage PPG of the first node ND1 connected to a gate of the first output transistor P_O1.

The second output transistor N_O1 may have a gate connected to the third node ND3 of the second differential mirror circuit 620 of the load stage 600, a source connected to the ground voltage VSS, and a drain connected to the output voltage VOUT. The current flowing in the second output transistor N_O1 may vary based on a voltage PNG of the third node ND3 connected to a gate of the second output transistor N_O1.

When gate voltages of the first and second output transistors P_O1 and N_O1 increase, the output voltage VOUT of the output stage 700 may decrease. On the other hand, when the gate voltages of the first and second output transistors P_O1 and N_O1 of the output stage 700 decrease, the output voltage VOUT of the output stage 700 may increase.

Specifically, according to one example, the first output transistor P_O1 may be formed of a PMOS transistor, and when the gate voltage PPG increases, a push current I_Push flowing from the first output transistor P_O1 to the output stage may decrease, and the second output transistor N_O1 may be formed of an NMOS transistor, and when the gate voltage PNG increases, a pull current I_Pull flowing from the output stage to the second output transistor N_O1 may increase. Accordingly, since the push current I_Push transmitted to the output stage decreases and the pull current I_Pull transmitted by the output stage increases, the output voltage VOUT output from the output stage may quickly decrease to quickly follow a falling transition of the input voltage.

In addition, according to another example, the first output transistor P_O1 may be formed of a PMOS transistor, and when the gate voltage PPG decreases, the push current I_Push flowing from the first output transistor P_O1 to the output stage may increase, and the second output transistor N_O1 may be formed of an NMOS transistor, and when the gate voltage PNG decreases, the pull current I_Pull flowing from the output stage to the second output transistor N_O1 may decrease. Accordingly, since the push current I_Push transmitted to the output stage increases and the pull current I_Pull transmitted by the output stage decreases, the output voltage VOUT output from the output stage may quickly increase to quickly follow a rising transition of the input voltage.

The first compensation capacitor C1 may have one end connected to the output voltage VOUT and the other end connected to the first differential mirror circuit 610. The second compensation capacitor C2 may have one end connected to the output voltage VOUT and the other end connected to the second differential mirror circuit 620. A slew rate of the output voltage VOUT with respect to the input voltage VIN may increase or decrease based on charging and discharging speeds of the first compensation capacitor C1 and the second compensation capacitor C2.

The amplifier AMP is a circuit for amplifying a signal of the input voltage VIN while following the input voltage VIN, and the operation of the amplifier will be described based on the circuits illustrated in FIGS. 5 and 6 as follows.

According to one example, in a state in which the input voltage VIN and the output voltage VOUT are equally a first voltage (e.g., VDD), when the input voltage VIN is changed to a second voltage (e.g., VSS) smaller than the first voltage, a voltage between the gate and source of the first input PMOS transistor P_I1 of the input stage 500, that is, a difference between the input voltage VIN and the power supply voltage VDD, is greater than a threshold voltage, the first input PMOS transistor P_I1 is turned on and a current flows, and thus the first differential current I_P1 has a value greater than zero. The first differential current I_P1 may increase further as the input voltage VIN decreases. In this case, the second differential current I_P2 may be continuously zero for a time in which the output voltage VOUT is not changed from the first voltage. That is, when the input voltage VIN changes from the first voltage to the second voltage, the first differential current I_P1 gradually increases, and the second differential current I_P2 is maintained at zero for a predetermined time.

In the second differential mirror circuit 620, since the first differential current I_P1 gradually increases and the second differential current I_P2 is maintained at zero for the predetermined time, a voltage of the fourth node ND4 is maintained at zero while a voltage of the third node ND3 gradually increases. At the same time, a voltage of the first node ND1 may also increase. Accordingly, the gate voltage PNG of the second output transistor N_O1 of the output stage 700 and the gate voltage PPG of the first output transistor P_01 gradually increase, and when a voltage between the source and the gate of the second output transistor N_O1 exceeds the threshold voltage, the second output transistor N_O1 may be turned on, and when a voltage between the source and the gate of the first output transistor P_01 gradually decreases and is lower than the threshold voltage, the first output transistor P_01 may be turned off to decrease the output voltage VOUT to the second voltage.

In addition, when the input voltage VIN changes from the first voltage to the second voltage lower than the first voltage, a voltage between the gate and the source of the first input NMOS transistor N_I1 of the input stage 500 (a difference between the input voltage VIN and the ground voltage VSS) gradually decreases, and the third differential current I_N1 also decreases, and when the voltage is lower than the threshold voltage, the third differential current I_N1 becomes zero. In this case, the fourth differential current I_N2 may increase as much as the third differential current I_N1 decreases. It is because the sum of the third differential current I_N1 and the fourth differential current I_N2 is equal to the second bias current I_B2.

In the first differential mirror circuit 610, when the fourth differential current I_N2 gradually increases and the third differential current I_N1 gradually decreases, a voltage of the second node ND2 decreases, and gate voltages of the first load PMOS transistor P_L1 and the second load PMOS transistor P_L2 decrease, and thus the current flowing in the second load PMOS transistor P_L2 may increase. In addition, since the amount of current flowing out as the third differential current I_N1 continuously decreases, the voltage of the first node ND1 may increase. At the same time, the voltage of the third node ND3 may also increase. Accordingly, the gate voltage PNG of the second output transistor N_O1 of the output stage 700 and the gate voltage PPG of the first output transistor P_01 gradually increase, and when a voltage between the source and the gate of the second output transistor N_01 exceeds the threshold voltage, the second output transistor N_O1 may be turned on, and when a voltage between the source and the gate of the first output transistor P_01 gradually decreases and is lower than the threshold voltage, the first output transistor P_01 may be turned off so that the output voltage VOUT may be decreased to the second voltage.

That is, in a state in which the input voltage VIN and the output voltage VOUT are equally the first voltage (e.g., VDD), when the input voltage VIN is changed to the second voltage (e.g., VSS) smaller than the first voltage, the first differential current I_P1 gradually increases, the second differential current I_P2 is continuously maintained at zero, the third differential current I_N1 decreases, and the fourth differential current I_N2 increases, and thus the gate voltage PNG of the second output transistor N_O1 and the gate voltage PPG of the first output transistor P_01 increase, and as a result, the first output transistor P_01 is turned off and the second output transistor N_O1 is turned on to change the output voltage VOUT to the second voltage to follow the change in input voltage.

In another example, in a state in which the input voltage VIN and the output voltage VOUT are equally a third voltage (e.g., VSS), when the input voltage VIN is changed to a fourth voltage (e.g., VDD) higher than the third voltage, a voltage between the gate and the source of the first input PMOS transistor P_I1 (a difference between the input voltage VIN and the power supply voltage VDD) gradually decreases, and the first differential current I_P1 also decreases, and when the voltage is lower than the threshold voltage, the first differential current I_P1 becomes zero. In this case, the second differential current I_P2 may increase as much as the first differential current I_P1 decreases. It is because the sum of the first differential current I_P1 and the second differential current I_P2 is equal to the first bias current I_B1.

In the second differential mirror circuit 620, when the first differential current I_P1 gradually decreases to zero and the second differential current I_P2 gradually increases, the voltage of the fourth node ND4 gradually increases, and thus gate voltages of the first load stage NMOS transistor N_L1 and the second load stage NMOS transistor N_L2 increase to turn on the first load stage NMOS transistor N_L1 and the second load stage NMOS transistor N_L2. Then, the voltage of the third node ND3 decreases. At the same time, the voltage of the first node ND1 also decreases. Accordingly, the gate voltage PNG of the second output transistor N_O1 of the output stage 700 and the gate voltage PPG of the first output transistor P_01 gradually decrease, and when the voltage between the source and the gate of the second output transistor N_O1 decreases to the threshold voltage or lower, the second output transistor N_O1 may be turned off, and when the voltage between the source and the gate of the first output transistor P_01 gradually increases and is higher than the threshold voltage, the first output transistor P_01 may be turned on to increase the output voltage VOUT to the fourth voltage.

In addition, when the input voltage VIN changes from the third voltage to the fourth voltage higher than the third voltage and a voltage between the gate and the source of the first input stage NMOS transistor N_I1, that is, the difference between the input voltage VIN and the ground voltage VSS, is higher than the threshold voltage, the first input stage NMOS transistor N_I1 is turned on and a current flows so that the third differential current I_N1 has a value greater than zero. The third differential current I_N1 may increase further as the input voltage VIN increases to be changed to the fourth voltage. In this case, the fourth differential current I_N2 may be continuously zero in a section in which the output voltage VOUT is not changed from the third voltage.

In the first differential mirror circuit 610, when the third differential current I_N1 gradually increases from zero and the fourth differential current I_N2 is maintained at zero, the voltage of the second node ND2 is maintained so that the first load PMOS transistor P_L1 and the second load PMOS transistor P_L2 may maintain the off state. In addition, since the amount of current flowing out as the third differential current I_N1 continuously increases, the voltage of the first node ND1 may decrease. At the same time, the voltage of the third node ND3 may also decrease. Accordingly, the gate voltage PNG of the second output transistor N_O1 of the output stage 700 and the gate voltage PPG of the first output transistor P_01 gradually decrease, and when the voltage between the source and the gate of the second output transistor N_O1 decreases to the threshold voltage or lower, the second output transistor N_O1 may be turned off, and when the voltage between the source and the gate of the first output transistor P_01 gradually increases and is higher than the threshold voltage, the first output transistor P_01 may be turned on to increase the output voltage VOUT to the fourth voltage.

That is, in a state in which the input voltage VIN and the output voltage VOUT are equally the third voltage (e.g., VSS), when the input voltage VIN is changed to the fourth voltage (e.g., VDD) higher than the third voltage, the first differential current I_P1 gradually decreases, the second differential current I_P1 gradually increases, the third differential current I_N1 increases, and the fourth differential current I_N2 is maintained at zero, and thus the gate voltage PNG of the second output transistor N_O1 and the gate voltage PPG of the first output transistor P_01 decrease, and as a result, the first output transistor P_01 is turned on and the second output transistor N_O1 is turned off to change the output voltage VOUT to the fourth voltage to follow the change in input voltage.

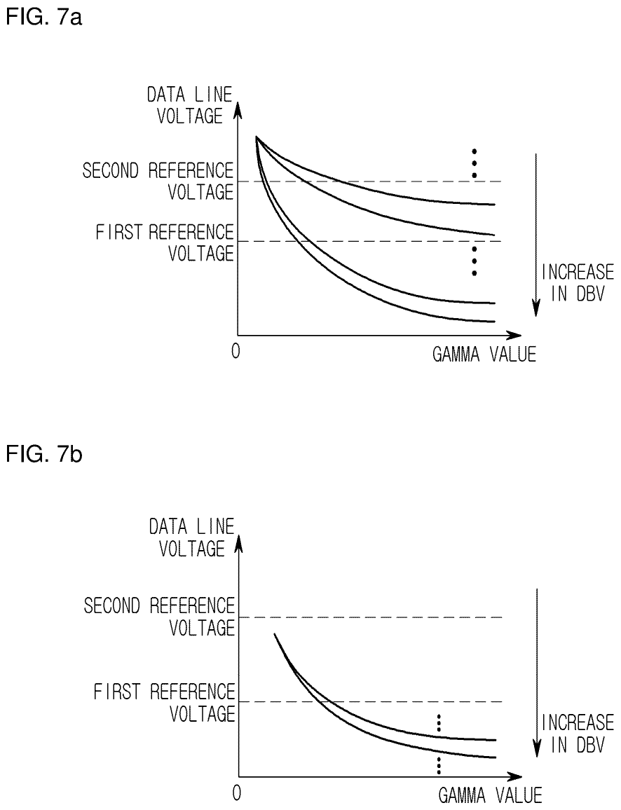

FIGS. 7a and 7b illustrate examples of data line voltages output to each channel by a source driver according to display DBVs and gamma values.

Referring to FIGS. 7a and 7b, a data line voltage according to each gamma value may be determined based on a set DBV. As illustrated in FIG. 2, when the pixel is driven by a PMOS transistor DT, a gamma value may increase as a data line DL_y voltage decreases. That is, the brightness of a display is proportional to the magnitude of a current flowing in an OLED, and in the case of the PMOS transistor, a voltage between a source and a gate increases as a voltage applied to a gate is low, thereby enabling more current to pass therethrough. Accordingly, a low data line voltage may correspond to a high gamma value which requests a brighter state, and a high data line voltage may correspond to a low gamma value.

Accordingly, as illustrated in FIGS. 7a and 7b, the higher the DBV is set to increase brightness, the lower the data line voltage may be.

In addition, when the DBV is set low, a maximum change in the data line voltage of each channel, which is changed at each horizontal scan time may not be great.

For example, referring to FIG. 7a and Table 1, when the DBV belongs to band 0, a minimum data line voltage may be 1.4 V, and a maximum data line voltage may be 5 V. Then, the maximum change in data line voltage, which is changed from a previous horizontal scan time to a current horizontal scan time, may be 3.6 V. Meanwhile, when the DBV belongs to band 11, the minimum data line voltage is 3.6 V, and thus the maximum change in data line voltage, which is changed from the previous horizontal scan time to the current horizontal scan time, may be 1.4 V. When the maximum change in data line voltage is great, both the first bias circuit 530 and the second bias circuit 540 may be used so that the output voltage VOUT may quickly follow the input voltage VIN, but when the maximum change in data line voltage is small, even if only one of the first bias circuit 530 and the second bias circuit 540 is used, the output voltage VOUT may follow the input voltage VIN within a predetermined time.

In the present disclosure, when the minimum data line voltage according to the DBV is set to be higher than a first reference voltage, the first bias circuit 530 may not be used. Then, since a bias current is not generated by the first bias circuit 530, the first input stage 510 is also turned off to reduce current consumption.

In addition, in the present disclosure, when the minimum data line voltage according to the DBV is set to be lower than a second reference voltage, the second bias circuit 540 may not be used. Then, since a bias current is not generated by the second bias circuit 540, the second input stage 520 is also turned off to reduce current consumption.

Table 1 shows an example in which a settable DBV is divided into 12 bands and a minimum data line voltage and first input stage on/off information are set for each band. In Table 1, the band section, the minimum data line voltage, and the first input terminal on/off setting may be variably set according to the characteristics of a display or a panel.

Referring to Table 1 and FIG. 7a, when the minimum data line voltage of the band is lower than the first reference voltage (e.g., 2.5 V), both the first bias circuit 530 and the second bias circuit 540 are used whereas, when the minimum data line voltage is higher than the first reference voltage, only the second bias circuit 540 may be used. Accordingly, since the first bias current I_B1 is not generated by the first bias circuit 530, the first input stage 510 is turned off to reduce current consumption.

As in FIG. 7b, when the maximum data line voltage of the band is lower than the second reference voltage (e.g., 5 V), only the first bias circuit 530 may be used. Accordingly, since the second bias current I_B2 is not generated by the second bias circuit 540, the second input stage 520 is turned off to reduce current consumption.

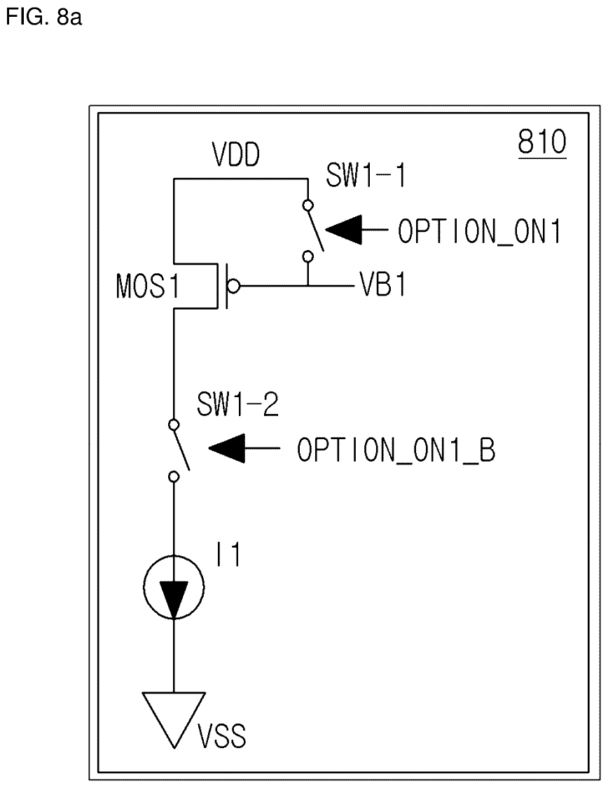

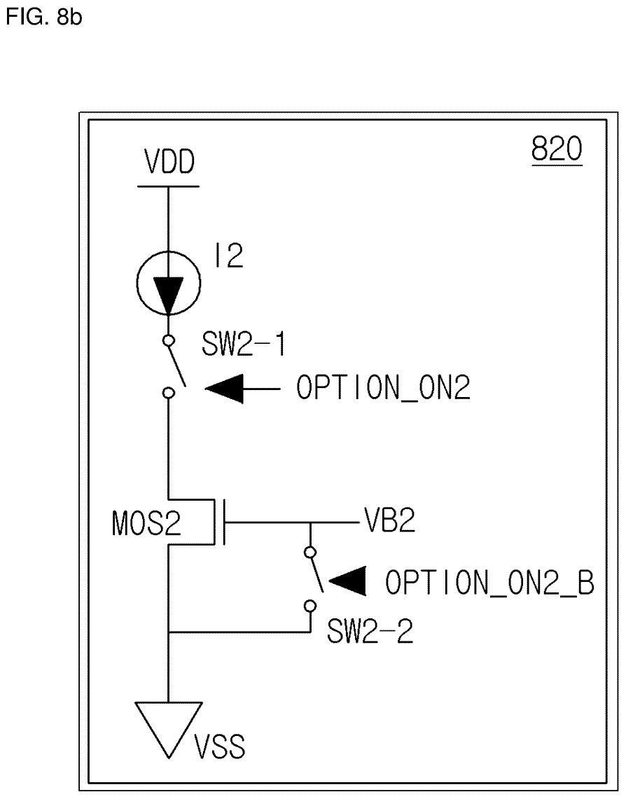

FIGS. 8a and 8b illustrate the bias control logic 210 illustrated in FIG. 1. The bias control logic 210 may include a first bias control logic 810 and a second bias control logic 820.

The first bias control logic 810 illustrated in FIG. 8a may include a 1-1 switch SW1-1, a 1-2 switch SW1-2, a first MOS MOS1, and a first current source 11. The 1-1 switch SW1-1 may be connected between the power supply voltage VDD and a gate terminal of the first MOS MOS1, and the 1-2 switch SW1-2 may be connected between a drain terminal of the first MOS MOS1 and the first current source 11. In addition, the 1-1 switch SW1-1 may be turned on according to a first option signal OPTION_ON1 of a high level to output the first bias control signal VB1, and the 1-2 switch SW1-2 may be turned on according to a first option complementary signal OPTION_ON1_B. The first option signal OPTION_ON1 and the first option complementary signal OPTION_ON1_B may operate complementarily to provide the first bias control signal VB1 to the source driver 300.

The second bias control logic 820 illustrated in FIG. 8b may include a 2-1 switch SW2-1, a 2-2 switch SW2-2, a second MOS MOS2, and a second current source 12. The 2-1 switch SW2-1 may be connected between a second current source 12 and a drain terminal of the second MOS MOS2, and the 2-2 switch SW2-2 may be connected between a gate terminal of the second MOS MOS2 and the ground voltage VSS. In addition, the 2-1 switch SW2-1 may be turned on according to a second option signal OPTION_ON2 of a high level to output the second bias control signal VB2, and the 2-2 switch SW2-2 may be turned on according to a second option complementary signal OPTION_ON2_B. The second option signal OPTION_ON2 and the second option complementary signal OPTION_ON2_B may operate complementarily to provide the second bias control signal VB2 to the source driver 300.

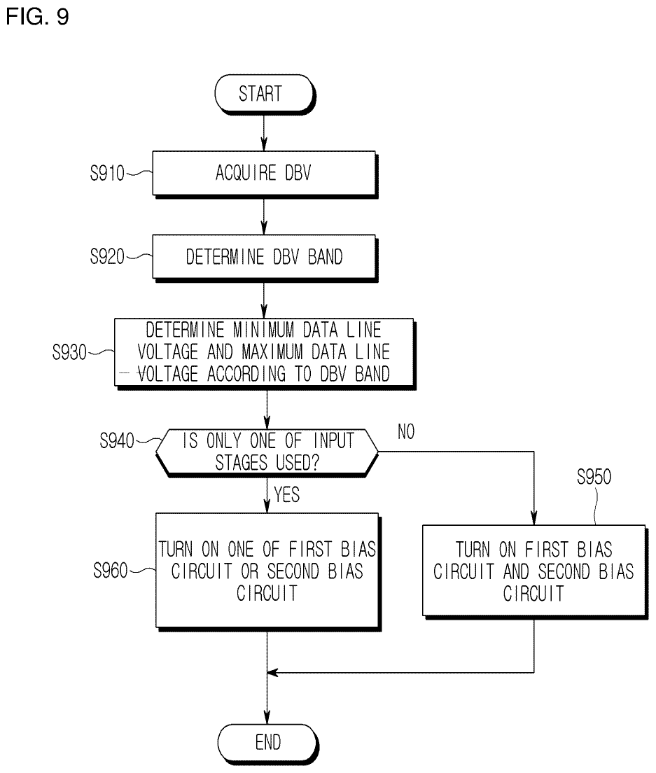

FIG. 9 illustrates a flowchart illustrating a method of determining whether to use only one of a first input stage or a second input stage according to the DBV.

According to one example, the operation of FIG. 9 may be performed by the bias control logic 210 of the timing controller 200, and the bias control signals VB1 and VB2 which are output as the result of the execution may be applied to all amplifiers APM1, AMP2, . . . , AMPn of all channels in the same manner.

Referring to FIG. 9, in operation S910, the timing controller 200 or the bias control logic 210 of the timing controller 200 may acquire a DBV. According to one example, the timing controller 200 or the bias control logic 210 may acquire the DBV through an input from a host. According to one example, the DBV may be changed for each frame. Accordingly, the timing controller 200 or the bias control logic 210 may perform the operation of FIG. 9 for each frame. According to one example, the host may provide the DBV set according to the manipulation of a user to the timing controller 200 or the bias control logic 210.

In operation S920, the timing controller 200 or the bias control logic 210 may determine a band to which the acquired DBV belongs. The band determined according to the DBV may have a range from the minimum to maximum data line voltage which are output in one frame. Accordingly, the range of the data line voltage which is output by the source driver 300 is different for each band, and the host may output the DBV differently according to the range of the data line voltage output in one frame to the timing controller 200 or the bias control logic 210. According to one example, the timing controller 200 or the bias control logic 210 may have the LUT shown in Table 1. The LUT shown in Table 1 may be preset by a user or a host, or the display device or the timing controller 200 may recognize the characteristics of the display panel 100 and automatically set the LUT based on the characteristics of the display panel 100. In the example of Table 1, the DBV may have 1024 values from 0 to 1023, and each value of the DBV may be set to belong to one of 12 bands. In addition, the minimum data line voltage may be set for each band.

The timing controller 200 or the bias control logic 210 may determine a band to which the acquired DBV belongs based on the preset LUT.

In operation S930, the timing controller 200 or the bias control logic 210 may determine the minimum data line voltage and the maximum data line voltage according to the DBV band. Here, the data line voltage may be a voltage output by the amplifier AMP. According to one example, the timing controller 200 or the bias control logic 210 may determine the minimum data line voltage and the maximum data line voltage of the DBV band determined based on the LUT as shown in Table 1.

In operation S940, the timing controller 200 or the bias control logic 210 may determine whether to use both the first input stage 510 and the second input stage 520 or only one of the two input stages. According to one example, the timing controller 200 or the bias control logic 210 may determine that both the first input stage 510 and the second input stage 520 are used when the determined minimum data line voltage is lower than the first reference voltage and the maximum data line voltage is higher than the second reference voltage. Alternatively, when the determined minimum data line voltage is higher than the first reference voltage, it may be determined that only one second input stage 520 is used. Alternatively, when the determined maximum data line voltage is lower than the second reference voltage, it may be determined that only one first input stage 510 is used.

According to one example, the result of the comparison between the minimum data line voltage and the reference voltage for each band may be added to the LUT as shown in Table 1. In addition, the result of the comparison between the maximum data line voltage and the reference voltage for each band may be added to the LUT. Then, without comparing the minimum data line voltage or the maximum data line voltage with the reference voltage for each frame, it is possible to determine whether to use both the first input stage 510 and the second input stage 520 or only one of the two input stages using the LUT, thereby reducing the operation time.

As the result of the determination in operation S940, when it is determined that both input stages are used, in operation S950, the timing controller 200 or the bias control logic 210 may output the first bias control signal VB1 as “L (e.g., VSS)” to turn on the first bias circuit 530 for providing the first bias current I_B1 to the first input stage and output the second bias control signal VB2 as “H (e.g., VDD)” to turn on the second bias circuit 540 for providing the second bias current I_B2 to the second input stage.

As the result of the determination in operation S940, when it is determined that only one of the two input stages is used, in operation S960, the timing controller 200 or the bias control logic 210 may output the bias control signal to prevent the operation of one of the first input stage 510 and the second input stage 520. According to one example, to operate the first input stage 510 and not to operate the second input stage 520, the first bias circuit 530 for providing the first bias current I_B1 may be turned on, and the second bias circuit 540 for providing the second bias current I_B2 may be turned off. To perform such an operation, the timing controller 200 or the bias control logic 210 may output the first and second bias control signals VB1 and VB2 as “L (e.g., VSS).” In addition, according to another example, not to operate the first input stage 510 and to operate the second input stage 520, the first bias circuit 530 for providing the first bias current I_B1 may be turned off, and the second bias circuit 540 for providing the second bias current I_B2 may be turned on. To perform such an operation, the timing controller 200 or the bias control logic 210 may output the first and second bias control signals VB1 and VB2 as “H (e.g., VDD).”

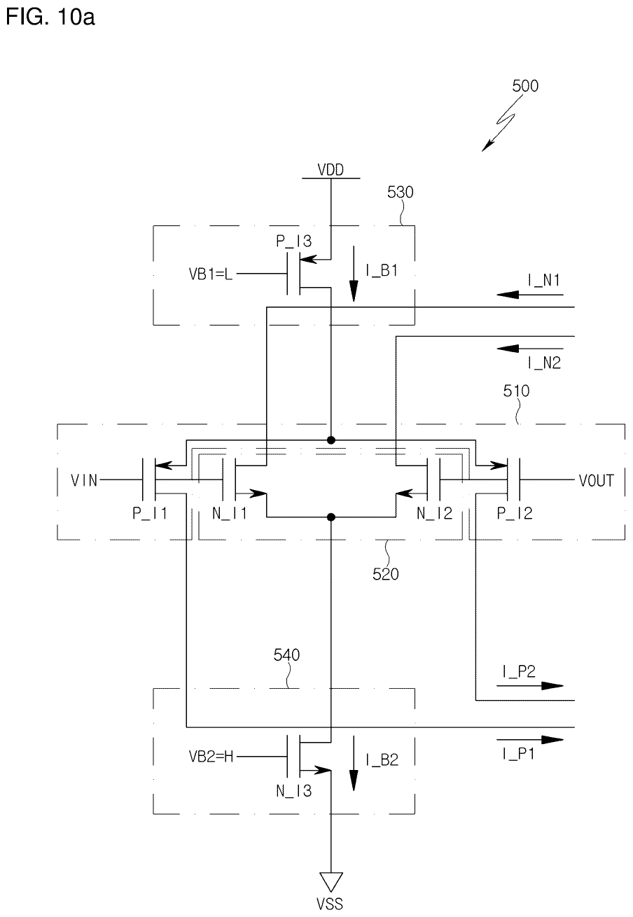

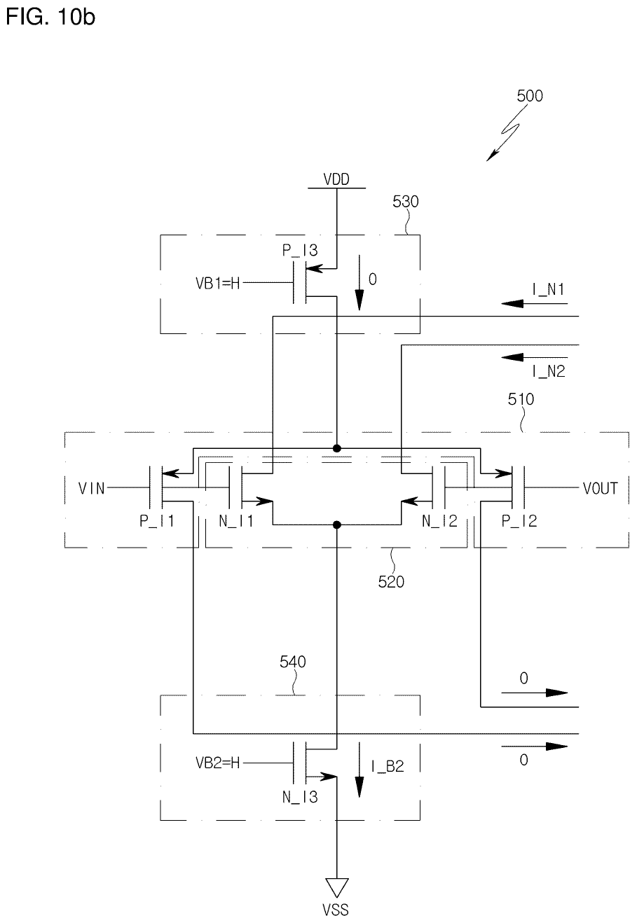

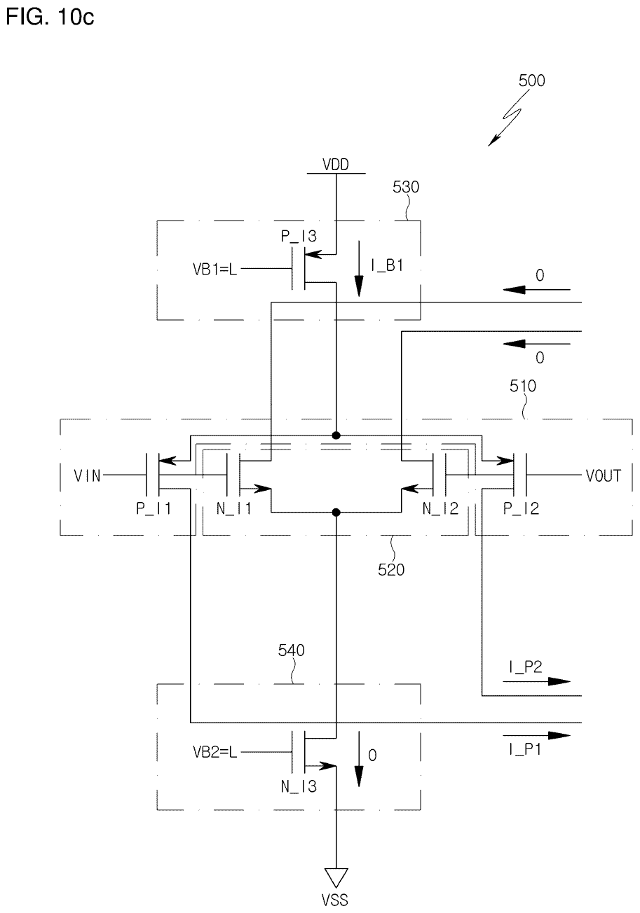

FIGS. 10a to 10c illustrate examples of the operation of an input stage controlled according to the operation of FIG. 9.

FIG. 10a illustrates an example in which, since the first bias control signal VB1 is “L” and the second bias control signal VB2 is “H,” both the first bias circuit 530 and the second bias circuit 540 may be operated. FIG. 10a illustrates an example in which, when the first and second bias circuits operate, the first bias current I_B1 and the second bias current I_B2 are provided to the first input stage 510 and the second input stage 520.

FIG. 10b illustrates an example in which, since both the first and second bias control signals VB1 and VB2 are “H,” the first bias circuit 530 does not supply the first bias current I_B1, and the second bias circuit 540 supplies the second bias current I_B2.

FIG. 10c illustrates an example in which, since both the first and second bias control signals VB1 and VB2 are “L,” the first bias circuit 530 supplies the first bias current I_B1, and the second bias circuit 540 does not supply the second bias current I_B2.

Accordingly, when the first bias current I_B1 or the second bias current I_B2 is not supplied, current consumption can be reduced. However, the current supply required for operating the load stage 600 can be reduced.

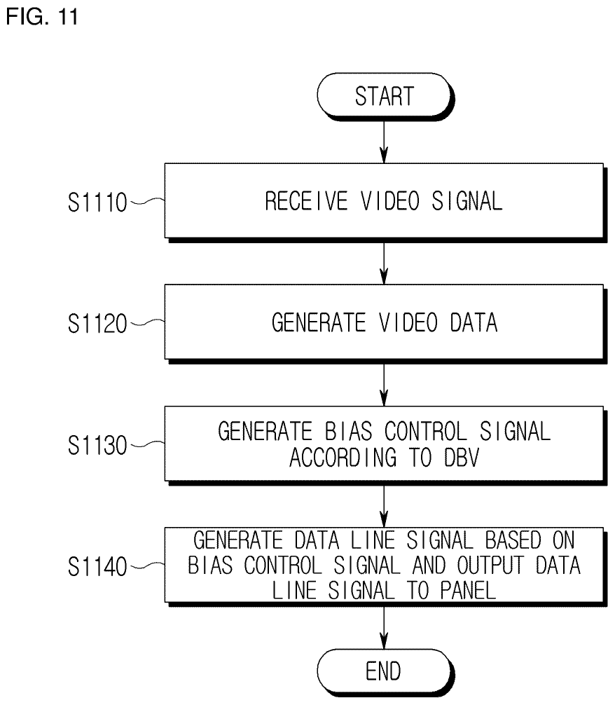

FIG. 11 illustrates a method of operating a display driving device according to one example of the present disclosure.

Referring to FIGS. 1 and 11, in operation S1110, the timing controller 200 of the display driving device may receive video signals RGB from the external source or a host. In addition, the display driving device may receive control signals and DBVs for frame control together.

In operation S1120, the timing controller 200 of the display driving device may generate video data DATA based on the received video signals RGB. The video data DATA may be generated according to a frame structure generated by the timing controller 200 and transmitted to the source driver 300.

In operation S1130, the bias control logic 210 of the timing controller 200 of the display driving device may determine whether to use the first bias circuit 530 and the second bias circuit 540 in one frame and generate a bias control signal accordingly. According to one example, the bias control logic 210 of the timing controller 200 may generate the bias control signal for operating only the first bias circuit 530, only the second bias circuit 540, or both the first bias circuit 530 and the second bias circuit 540.

In operation S1140, the source driver 300 of the display driving device may generate data line voltages for each channel based on the bias control signal for controlling the operation of the first bias circuit 530 and the second bias circuit 540 and output the data line voltages to the display panel 100.

At this time, all channel amplifiers AMP may acquire the same bias control signal to operate only the first bias circuit 530 or only the second bias circuit 540 in the same manner or acquire different bias control signals to operate both the first bias circuit 530 and the second bias circuit 540. That is, the operation of the first bias circuit 530 and the second bias circuit 540 is not different for each channel, but the first bias circuit 530 and the second bias circuit 540 may operate or not operate in all channels.

As described above, according to the present disclosure, it is possible to reduce power consumption by controlling whether to use the bias circuit of the input stage 500 side used by the source amplifier provided in the source driver 300 to output the data line voltages to the display panel 100.

According to one example of the present disclosure, by controlling the current of the input stage included in the output circuit of the source driver according to the DBV, it is possible to reduce current consumption in the display device.

Effects obtainable from the present disclosure are not limited to the above-described effects, and other effects that are not described will be able to be clearly understood by those skilled in the art to which the present disclosure pertains from the following description.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. A display driving device for driving a display panel, comprising:
a timing controller configured to output a bias control signal and video data based on a display brightness value (DBV) received from an external source; and
a source driver configured to output a data line voltage to a plurality of channels based on the bias control signal and the video data,
wherein the timing controller is configured to generate the bias control signal independently of a variation of the data line voltage.

2. The display driving device of claim 1, wherein the source driver comprises:
an input circuit configured to output the video data distinguished based on a channel of the source driver by distinguishing the video data which is input based on a line;
a conversion circuit configured to output an analog voltage corresponding to the video data distinguished based on the channel; and
an output circuit configured to output the data line voltage to the display panel based on the analog voltage and the bias control signal.

3. The display driving device of claim 2, wherein the output circuit comprises a plurality of amplifiers provided in each channel of the source driver and configured to amplify the analog voltage based on the bias control signal and output the data line voltage.

4. The display driving device of claim 1, wherein the timing controller comprises:
a first bias control logic configured to generate a first bias control signal; and
a second bias control logic configured to generate a second bias control signal.

5. The display driving device of claim 4, wherein the first bias control logic is configured to provide the first bias control signal to the source driver according to a first option signal of a high level and a first option complementary signal of a low level.

6. The display driving device of claim 4, wherein the second bias control logic is configured to provide the second bias control signal to the source driver according to a second option signal of a high level and a second option complementary signal of a low level.

7. The display driving device of claim 3, wherein each amplifier comprises:
an output stage comprising a first output transistor and a second output transistor; and
an input stage comprising:
a first bias circuit configured to provide a first bias current,
a first input stage configured to determine a first differential current and a second differential current, which correspond to a difference between an input voltage and an output voltage, based on the first bias current,
a second bias circuit configured to provide a second bias current, and
a second input stage configured to determine a third differential current and a fourth differential current, which correspond to a difference between the input voltage and the output voltage, based on the second bias current,
wherein the first bias circuit is configured to provide or not provide the first bias current based on the bias control signal, and
wherein the second bias circuit is configured to provide or not provide the second bias current based on the bias control signal.

8. The display driving device of claim 7, wherein each amplifier further comprises a load stage configured to control gate voltages of the first output transistor and the second output transistor based on the first differential current and the second differential current which are applied from the input stage and the third differential current and the fourth differential current which are transmitted to the input stage.

9. The display driving device of claim 7, wherein the timing controller is configured to:
classify settable display brightness values (DBVs) into a plurality of bands;
set a minimum and maximum data line voltage for each band;
determine a first band to which the received DBV belongs; and
compare the minimum and maximum data line voltage of the first band with a reference voltage and generate the bias control signal.

10. The display driving device of claim 9, wherein, when the minimum data line voltage of the first band is lower than a first reference voltage and the maximum data line voltage of the first band is higher than a second reference voltage, the timing controller is configured to generate the bias control signal which allows the first bias circuit and the second bias circuit to provide the first bias current and the second bias current.

11. The display driving device of claim 9, wherein, when the minimum data line voltage of the first band is higher than a first reference voltage, the timing controller is configured to generate the bias control signal which allows the second bias circuit to provide the second bias current.

12. The display driving device of claim 9, wherein, when the maximum data line voltage of the first band is lower than a second reference voltage, the timing controller is configured to generate the bias control signal which allows the first bias circuit to provide the first bias current.

13. The display driving device of claim 9, wherein the timing controller comprises a lookup table (LUT) for generating the bias control signal, the LUT including a minimum and maximum data line voltage corresponding to a band to which each DBV belongs and a bias control signal corresponding to each band, and
wherein the timing controller is configured to generate the bias control signal according to the received DBV based on the LUT.

14. A method of operating a display driving device for driving a display panel, the method comprising:
receiving a video signal to be displayed on the display panel;
generating video data according to a frame structure based on the video signal;
generating a bias control signal based on a display brightness value (DBV) received from an external source;
determining whether a first bias control circuit and a second bias control circuit, which are provided in an input stage of an amplifier included in a source driver, provide a first bias current and a second bias current based on the bias control signal; and
generating a data line voltage based on at least one of the first bias current and the second bias current and the video data and outputting the generated data line voltage to the display panel,
wherein the bias control signal is generated independently of a variation of the data line voltage.

15. The method of claim 14, wherein the generating of the data line voltage based on the video data and the outputting of the generated data line voltage to the display panel comprise:
distinguishing the video data, which is input based on a line, based on a channel of the source driver and outputting the distinguished video data;
outputting an analog voltage corresponding to the video data distinguished based on the channel; and
amplifying the analog voltage based on at least one of the first bias current and the second bias current based on the channel and outputting the amplified analog voltage to the display panel.

16. The method of claim 14, wherein the generating of the bias control signal based on the DBV received from the external source comprises:
classifying settable DBVs into a plurality of bands;
setting a minimum and maximum data line voltage for each band;
determining a first band to which the received DBV belongs; and
comparing the minimum and maximum data line voltage of the first band with a reference voltage and generating the bias control signal.

17. The method of claim 16, wherein the comparing of the minimum and maximum data line voltage of the first band with the reference voltage and the generating of the bias control signal comprise:
generating the bias control signal which allows the first bias circuit and the second bias circuit to provide the first bias current and the second bias current when the minimum data line voltage of the first band is lower than a first reference voltage and the maximum data line voltage is higher than a second reference voltage.

18. The method of claim 16, wherein the comparing of the minimum and maximum data line voltage of the first band with the reference voltage and the generating of the bias control signal comprise:
generating the bias control signal which allows the second bias circuit to provide the second bias current when the minimum data line voltage of the first band is higher than a first reference voltage.

19. The method of claim 16, wherein the comparing of the minimum and maximum data line voltage of the first band with the reference voltage and the generating of the bias control signal comprise:
generating the bias control signal which allows the first bias circuit to provide the first bias current when the maximum data line voltage of the first band is lower than a second reference voltage.

20. The method of claim 16, wherein the comparing of the minimum and maximum data line voltage of the first band with the reference voltage and the generating of the bias control signal comprise:
setting a lookup table (LUT) including a minimum and maximum data line voltage corresponding to a band to which each DBV belongs and a bias control signal corresponding to each band; and
generating the bias control signal according to the DBV based on the LUT.
